(19) United States
(12) Patent Application Publication
(10) Pub. No.: US 2023/0090188 A1
(43) Pub. Date: Mar. 23, 2023

(54) MULTI LAYER PACKAGE SUBSTRATE HAVING DIFFERENT DIELECTRIC MATERIALS FOR METAL LAYERS WITH DIFFERENT CIRCUIT STRUCTURES

(71) Applicant: Intel Corporation, Santa Clara, CA (US)

(72) Inventors: Junxin WANG, Gilbert, AZ (US); Kemal AYGUN, Tempe, AZ (US); Jieying KONG, Chandler, AZ (US); Ala OMER, Chandler, AZ (US); Whitney M. BRYKS, Tempe, AZ (US)

(21) Appl. No.: 17/481,001

(22) Filed: Sep. 21, 2021

(51) Int. Cl. H01L 25/065; H01L 23/31; H01L 23/538

(52) U.S. Cl. CPC H01L 25/0652; H01L 23/31; H01L 23/5385; H01L 23/5386

(57) ABSTRACT

An apparatus is described. The apparatus includes a semiconductor chip package substrate having alternating metal and dielectric layers. First and second ones of the dielectric layers that are directly above and directly below a first of the metal layers that is patterned to have supply and/or reference voltage structures have respectively higher dielectric constant (Dₖ) and higher dissipation factor (D_{f}) than third and fourth ones of the dielectric layers that are directly above and directly below a second of the metal layers that is patterned to have signal wires that are to transport signals having a pulse width of 1 ns or less.

### FIELD OF INVENTION

The field of invention pertains generally to the mechanical arts and, more specifically, to a multi layer package substrate having different dielectric materials for metal layers with different circuit structures.

### BACKGROUND

Both computers and networks continue to pack higher and higher levels of performance into smaller and smaller packages. Packaging engineers therefore have to invent creative package solutions to keep pace with the packaging requirements of such aggressively designed systems and their corresponding components.

### FIGURES

A better understanding of the present invention can be obtained from the following detailed description in conjunction with the following drawings, in which:

FIG. 1 shows a semiconductor chip package (prior art);

FIG. 2 shows a lumped element circuit model;

FIG. 3 shows an improved multi-layer package substrate;

FIG. 4 shows a section of an improved multi-layer substrate;

FIGS. 5a, 5b, 5c, 5d, 5e and 5f show a method of manufacturing an improved multi-layer substrate;

FIGS. 6a and 6b show other semiconductor chip packages (prior art);

FIG. 7 shows a computing system.

### DETAILED DESCRIPTION

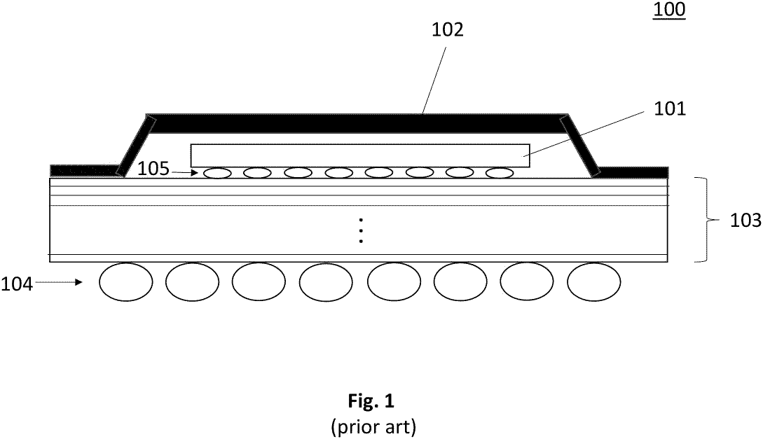

FIG. 1 shows a cross section 100 of a packaged semiconductor chip 101. As observed in FIG. 1, the chip package includes a lid 102 (also referred to as integrated heat spreader (IHS)) that is mounted to the package substrate 103. The package substrate 103 is a multi-layer circuit board that connects the package input/outputs (I/Os) 104 to their corresponding chip I/Os 105.

More specifically, the package substrate 103 is a stack of alternating dielectric and metal layers that are specially patterned to form the wires that connect the package I/Os 104 to their corresponding chip I/Os 105. Over time, the number of I/Os 105 per semiconductor chip 101 has steadily increased as the size and complexity of semiconductor chips has increased with each new generation of semiconductor chip manufacturing technology.

Likewise, the density of the wiring structures within the package substrate 103 have also increased to keep up with the increasing number of chip I/Os 105. The continually increasing wiring density is presenting problems concerning the choice of material for the package substrate’s dielectric layers. Here, to simplify the substrate manufacturing process, each dielectric layer in the package substrate 103 is traditionally composed of the same dielectric material (e.g., silicon dioxide (SiOz), silicon nitride (Si₃N₄), FR4, etc.).

Different wire structures within the package substrate 103, however, have different electrical purposes. As a consequence, particularly with the shrinking dielectric layer thicknesses and narrower wire cross sections associated with increasing wiring density, it is becoming increasing difficult to use the same dielectric material as the electrical isolation between each wiring layer in the substrate.

Generally, there are high speed signal wires and there are power supply or reference wires (power supply or reference wires are actually implemented mostly as “planes” but for ease of discussion will be referred to hereafter as “wires” or “circuit structures”). High speed signals typically have a pulse width of 1 ns or less. High speed signals wires propagate cleaner signals (e.g., having sharper rise and fall times) the lower the shunt capacitance and the higher the shunt resistance. By contrast, power supply or reference wires will provide cleaner supply or voltage references (e.g., less noisy and more stable) the higher the shunt capacitance and the lower the shunt resistance.

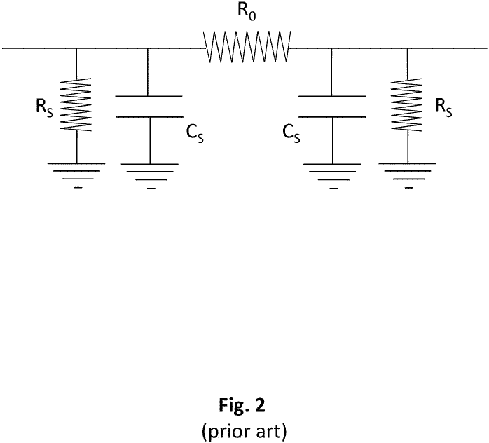

FIG. 2 illustrates these principles in more detail. FIG. 2 shows a lumped element circuit model for either a high speed signal wire or a supply/reference wire. As observed in FIG. 2, the lumped element circuit model includes a series resistance Ro, shunt capacitances Cs and shunt resistances Rₛ. The value of the series resistance Rₒ is mostly a function of the length of the wire and the cross sectional dimensions of the wire (the longer the wire and the narrower the wire the higher the wire’s series resistance Ro).

The shunt capacitances Cs and shunt resistances Rs are attributes of the dielectric layers in the package substrate’s multi-layer stack that reside above and below the metal layer that was patterned to form the wire. The value of the shunt capacitances Cs is proportional to a dielectric constant (Dₖ) that is specific to the particular chosen dielectric material and inversely proportional to the thickness of the dielectric.

For high speed signals it is important that the shunt capacitances Cs maintain a high impedance (otherwise high speed signals will lose signal energy as they propagate down the wire). For high speed signals, the impedance X of the shunt capacitances Cs is inversely proportional to the value of their capacitance (X = ⅟j ω) Cₛ). Thus, to maintain a high impedance for a high speed signal wire, ideally, the shunt capacitances Cs have very small capacitance which, in turn, corresponds to a dielectric material having small Dₖ and large thickness.

Unfortunately, as discussed above, there are increasingly more wires in the package substrate 103 with each next generation of semiconductor chip technology. This drives more layers per substrate 103 and, correspondingly, thinner dielectric materials (to pack more layers into the package substrate while keeping the vertical profile of the package small) which, in turn, drives a need for even lower Dₖ dielectric materials. Thus, for high speed signal wires, low Dₖ is a pertinent parameter.

Apart from low Dₖ, a high speed signal wire will also better propagate a high speed signal if the shunt resistances Rs are high. Here, the transmission of a high speed signal on a wire can be simplistically modeled as the presence of an oscillating signal on the wire. Over time, an oscillation will dissipate its signal energy (the amplitude of the oscillation lessens) through the shunt resistances Rs.

Another constant that is specific to the particular material chosen for the dielectric, referred to as the dissipation factor (D_{f}), is proportional to the amount of signal energy that is lost through the shunt resistances Rₛ per oscillation cycle. More specifically, D_{f} is related to the ratio of the current that flows through the shunt resistances Rs to the current that flows through the shunt capacitances Cs per oscillation cycle.

Because it is desirable to maintain the strength of the signal on the wire, a small D_{f} is desired for the dielectric material (much less current flows through the shunt resistances Rs than the shunt capacitances Cₛ per oscillation cycle, which, in turn, corresponds to a very high shunt resistance). Thus, dielectric materials having low Dₖ and low D_{f} are best suited for high speed signal wires.

By contrast, supply/reference voltage wires will perform better the higher the shunt capacitances Cₛ and the lower shunt resistances Rₛ for precisely the opposite reasons described just above for high speed signal wires. Specifically, whereas high speed signal wires ideally preserve high frequency signal energy, by contrast, supply/reference voltage wires ideally eliminate high frequency signal energy. That is, ideally, a supply or reference voltage remains constant over time (the supply/reference does not fluctuate). Noise is voltage fluctuations that are induced on a supply/reference wire by the existence of rapidly switching signals on nearby wires and/or driving rapidly switching signals with circuits that are supplied/referenced by the supply/reference wire.

Regardless, the voltage fluctuations have high frequency signal components and are therefore akin to high speed signals. Thus, unlike high speed signal wires, supply/reference wires are ideally designed to eliminate high frequency signal components. This can be accomplished by increasing the shunt capacitances Cₛ and decreasing the shunt resistances Rₛ, which, in turn, corresponds to a higher Dₖ and higher D_{f} dielectric material at least as compared to the Dₖ and D_{f} of the dielectric material that neighbors a high speed signal wire.

Thus, a more optimal design approach includes employing different dielectric materials in the package substrate stack 103. Specifically, where possible, a first dielectric material having low Dₖ and low D_{f} is used to neighbor a high speed signal wire layer, and, a second dielectric material having higher Dₖ and higher D_{f} than the first dielectric material is used to neighbor a supply/reference wire layer.

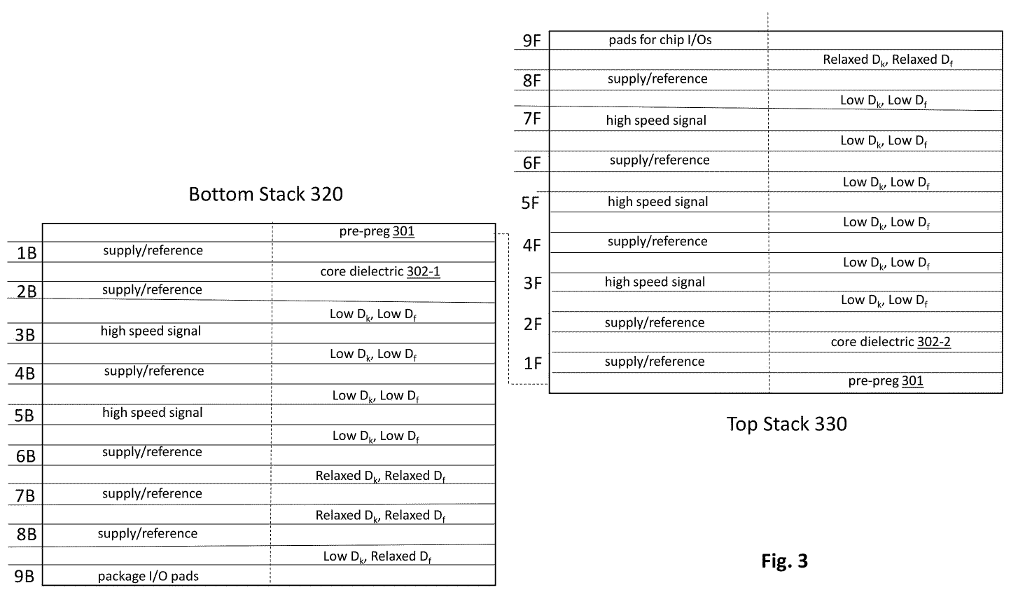

FIG. 3 shows an embodiment of a package substrate stack 300 that has been designed according to the above described approach. As will be explained in more detail with respect to FIG. 3, different dielectric layers are implemented with different dielectric materials depending on the use of the metal wiring layers that neighbor them.

As observed in FIG. 3, the substrate stack 300 has a middle layer composed of prepreg 301. The substrate is formed by stacking alternating metal and dielectric layers on both sides of the prepreg 301. Thus, there is a bottom stack 320 that increments the layer count moving downward beneath the prepreg 301, and, there is a top stack 330 that increments the layer count moving upward above the prepreg 301.

Only metal layers are counted. Thus, moving downward from the prepreg 301, the metal layers in the bottom stack 320 are counted as 1B, 2B, 3B, etc. A specific dielectric layer in the bottom stack 320 is identified by the pair of metal layers it is sandwiched between. So, for example, the first dielectric layer in the bottom stack 302-1 is identified as “1B-2B”, the second dielectric layer in the bottom stack is identified as “2B-3B”, etc.

Likewise, moving upward from the prepreg 301, the metal layers in the top stack 330 are counted as 1F, 2F, 3F, etc. A specific dielectric layer in the top stack 330 is identified by the pair of metal layers it is sandwiched between. So, for example, the first dielectric layer in the top stack 302-2 is identified as “1F-2F”, the second dielectric layer in the bottom stack is identified as “2F-3F”, etc.

FIG. 3 depicts the various metal and dielectric layers as separate rows along a pair of columns. A leftmost column describes the predominant use of the wiring structures that exist at each metal layer. A rightmost column depicts the dielectric material between each metal layer characterized according to one of the following design choices: 1) low Dₖ and low D_{f}; 2) relaxed Dₖ and relaxed D_{f}; 3) low Dₖ and relaxed D_{f}. Here, “relaxed Dₖ” means the Dₖ of the material is higher than a dielectric having low Dₖ. Likewise, “relaxed D_{f}” means the D_{f} of the material is higher than a dielectric having low D_{f}.

Notably, the 1B-2B and 1F-2F dielectric layers 302-1, 302-2 are considered “core” dielectric layers because they are near the prepreg 301 and therefore play the additional role of acting as a kind of substrate for the bottom and top stacks 330, 320. That is, the 1B-2B and 1F-2F dielectrics 302-1, 302-2 have mechanical/structural requirements that cause them to be implemented with a material (e.g., glass cloth) other than the kinds of materials that would be good candidates for the three design choices specified just above.

Additionally, the primary dielectric on the underside of the bottom stack 330 (beneath the 9B metal layer) and on top of the top stack 320 (on top of the 9F metal layer) is solder resist and is not considered part of the substrate multi-layer stack.

Thus, the remaining dielectric layers of concern are each of the dielectric layers between the 2B and 9B metal layers of the bottom stack 330, and, each of the dielectric layers between the 2F and 9F metal layers of the top stack 320.

With respect to the bottom stack 330, each of the 3B, 4B and 5B metal layers predominantly have high speed signal wires. As such, a low Dₖ and low D_{f} dielectric is appropriate for each of the 2B-3B, 3B-4B, 4B-5B and 5B-6B dielectric layers so that each of the 3B, 4B and 5B metal layers are surrounded with a low Dₖ and low D_{f} dielectric. By contrast, the 6B, 7B and 8B metal layers are predominantly used for supply and reference wires. As such, the 6B-7B and 7B-8B dielectric layers are implemented with relaxed Dk and relaxed Df dielectric material.

The 9B metal layer is the exposed metal surface on the bottom of the substrate where, e.g., pads or lands for the package’s I/Os (e.g., solder balls) are formed. The 8B-9B dielectric is a low Dₖ dielectric material (as opposed to a low Dₖ and low D_{f} dielectric) because the pads/lands are circuit structures having large surface area and short length. As such, shunt capacitance is much more of a concern than series resistance or shunt resistance. The appropriate dielectric therefore emphasizes low Dₖ with less concern for D_{f} (low Dₖ and relaxed D_{f}). In various embodiments, a “low Dₖ and relaxed D_{f}” material that neighbors an exposed metal layer (such as the 8B-9B dielectric layer) has a smaller Dₖ than a “low Dₖ and low D_{f}” dielectric material that neighbors a high speed signal wire layer (the D_{f} may be the same as or higher than the D_{f} of a low Dₖ and low D_{f} dielectric).

With respect to the top stack 320, high speed signal wires are predominantly present in each of the 3F, 5F and 7F metal layers. As such, a low Dₖ and low D_{f} dielectric is appropriate for each of the 2F-3F, 3F-4F, 4F-5F, 5F-6F, 6F-7F and 7F-8F dielectrics. Here, even though the 2F, 4F, 6F and 8F metal layers are predominantly used for supply/reference wires, the importance of preserving the signal integrity on the high speed signal wires takes priority over the desire to eliminate noise on the supply/reference wires. As such, all dielectric layers that neighbor a metal layer having predominantly high speed signal wires are chosen to be low Dₖ and low D_{f} dielectrics.

The 9F metal layer is the exposed metal surface on the top of the substrate where pads or lands for the chip’s I/Os (e.g., solder bumps) are formed. Here, the pads/lands for the chip I/Os are much smaller than the pads/lands for the package I/Os. Thus, shunt capacitance is less of a concern for the pads/lands on the top of the substrate than on the bottom of the substrate. As such, an extremely low Dₖ dielectric as is used for the 8B-9B dielectric, is not necessary for the 8F-9F dielectric and the low Dₖ and low D_{f} dielectric that is used for the high speed wire layers is sufficient.

In various embodiments the high speed signal wires transport signals associated with high speed interfaces such as any/all of: 1) a Joint Electron Device Engineering Council (JEDEC) dual data rate (DDR) memory interface (e.g., DDR4, DDR5, etc.); 2) an OpenCAPI Consortium Coherent Accelerator Processor Interface (CAPI); 3) Advanced Micro Devices (AMD) Infinity Fabric interface; 4) a Peripheral Component Interface (PCI) Special Interest Group (SIG) PCI Express (PCle) interface; and, 5) an Institute of Electrical and Electronic Engineers (IEEE) 802.3 Ethernet interface, among other possible types of high speed signal wires.

In various embodiments, low Dₖ is achieved with a “hollow filler” material structure. With hollow filler dielectrics, air pockets are deliberately integrated into the dielectric material. Air has extremely low permittivity (almost no electrical dipole moments can be induced) which translates into low Dₖ. Certain hollow filler dielectrics create the air pockets by inserting hollow particles into the dielectric medium.

In various embodiments, a higher Dₖ (such as the Dₖ of dielectric layers having a relaxed Dₖ) is achieved by not incorporating air pockets into the dielectric medium.

In various embodiments, a low D_{f} is achieved by incorporating non-polar cross-linkers and/or non-polar polymer backbone material into the dielectric material. Here, “non polar” means that the molecular structures within the dielectric have little/no electric charge that can move or otherwise respond to an applied electric field that, in turn, would correspond to an electrical current within the dielectric. Such emphasis on minimizing current translates into higher resistance. At very high frequencies the molecular structures of some materials, including dielectrics, can be induced to respond in a way that corresponds to an electrical current that flows through the dielectric. Low D_{f} materials are designed to keep such currents minimal over the frequency span of interest.

Based on the above, a partial list of suitable low Dk and low Df materials include hollow silicon dioxide (SiO₂) filler materials, epoxy based polymers without polar groups, maleimide based polymers and benzocyclobutene polymers. By contrast, a partial list of relaxed Dk and relaxed Df materials includes SiO₂ filler materials, micron or nano size SiO₂ filler materials, mixture of hollow SiO₂ filler with SiO₂ filler materials and epoxy based polymers. Moreover, a partial list of low Dk and relaxed Df materials includes SiO₂ filler materials, epoxy based polymers, and epoxy based polymers with presence of polar groups.

It is pertinent to point out that for high speed signal wires, the D_{f} parameter becomes increasingly important, perhaps even more important than the Dₖ parameter, the longer the wire. Here, as the wire lengthens its series resistance increases, which, in turn increases the resistive loss of the signal through the wire. As such, there is less tolerance for resistive loss of the signal through the shunt resistances.

In various embodiments, therefore, the longer the high speed wire, the more emphasis is placed on lowering Dₖ, possibly at the expense of higher Dₖ. For example, a long high speed signal wire could have higher Dₖ and lower D_{f} than a shorter high speed signal wire. It is conceivable, therefore, that at least one metal layer could be reserved for long high speed signal wires, and, such metal layers are neighbored by a first dielectric material having higher Dₖ and lower D_{f} than the dielectric material(s) used for other high speed wires having shorter lengths.

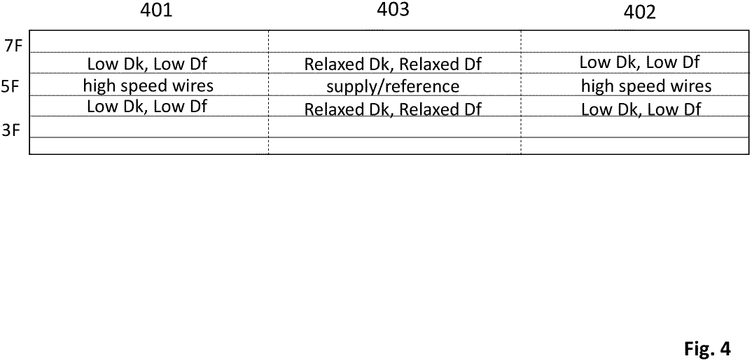

FIG. 4 shows an extension of the teachings above where both supply/reference wires and high speed wires exist at a same metal layer and the surrounding dielectric layers are patterned to have different types of dielectric materials along a same dielectric layer level to better surround the corresponding wires. FIG. 4 shows a particular example where the 5F metal layer is patterned to include two regions of high speed wires 401, 403 and a single region 402 of supply/reference wires.

As observed in FIG. 4, the dielectric layers on either side of the 5F metal layer are partitioned into a pair of low Dₖ and low D_{f} dielectric regions 401, 403 (to better serve the high speed wires) and a region of relaxed Dₖ and relaxed D_{f} dielectric 402. The pattern can continue vertically through the other layers of the stack.

In order to form the dielectric regions 401, 402, 403, in various embodiments, during construction of the dielectric layer for the stack, one of the dielectric material types (e.g., low Dₖ and low D_{f}) is completely and uniformly deposited on the exposed surface stack. Then, the deposited dielectric is patterned and etched to create openings for the other dielectric material type (e.g., relaxed Dₖ and relaxed D_{f}).

For example, referring to FIG. 4, if the initial dielectric coating across the entirety of the exposed stack surface is low Dₖ and low D_{f}, then, the dielectric layer is patterned and etched in region 402. The etched region 402 is then filled with relaxed Dₖ and relaxed D_{f} dielectric.

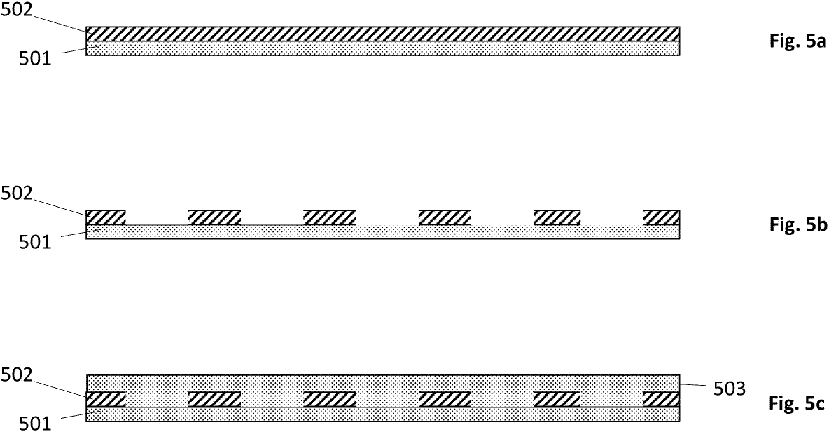

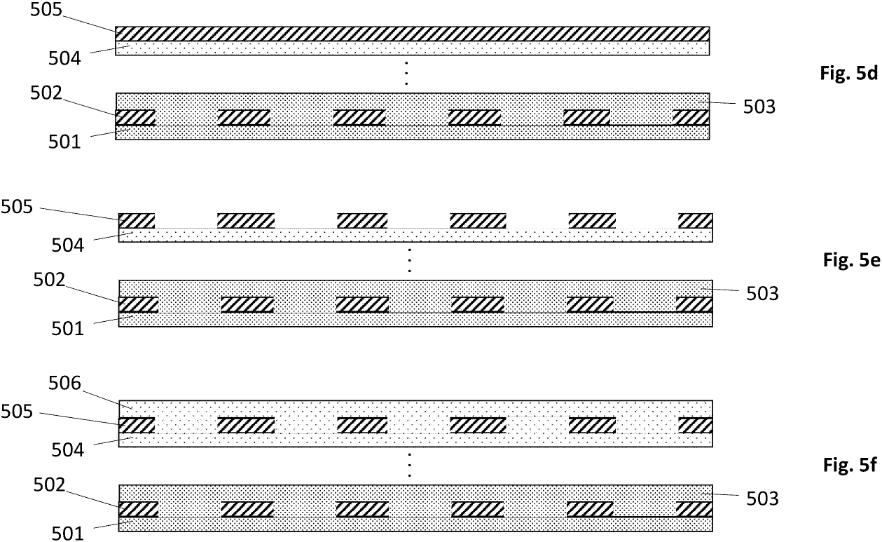

FIGS. 5a through 5f shows a method of making a package substrate as discussed above. FIG. 5a shows a first metal layer 502 being deposited on a first dielectric layer 501. FIG. 5b shows the first metal layer 502 after it has been patterned (e.g., with photolithographic techniques) to form high speed wires. FIG. 5c shows a second dielectric layer 503 being deposited on the patterned metal layer 502. The first and second dielectrics 501, 503 have a dielectric constant Dₖ and a dissipation factor D_{f}.

FIG. 5d shows a second metal layer 505 being deposited on a third dielectric layer 504 (the third dielectric layer 504 is a few layers above dielectric layer 503). FIG. 5e shows the second metal layer 505 after it has been patterned (e.g., with photolithographic techniques) to form supply/reference voltage circuit structures. FIG. 5f shows a fourth dielectric layer 506 being deposited on the second metal layer 505. The third and fourth dielectric layers 504, 506 have a dielectric and dissipation factors that are higher than the dielectric and dissipation factors of the first and second dielectric layers 501, 503.

Although embodiments above have indicated there is only one semiconductor chip per package, there are packages having multi-layer substrates that package more than one semiconductor chip in a single package.

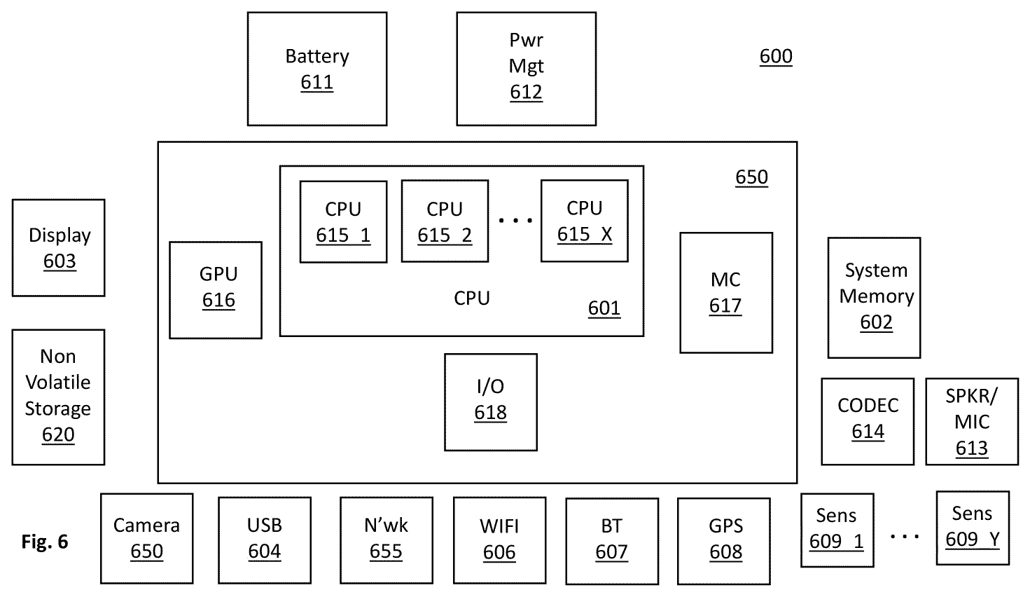

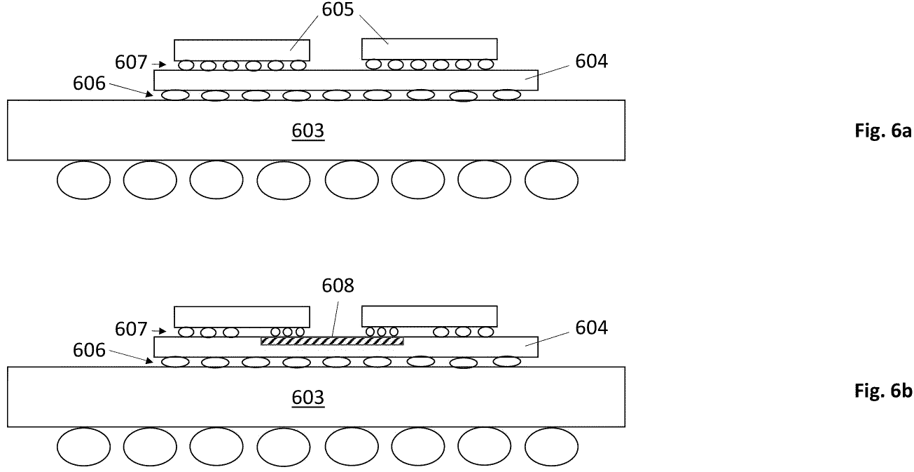

FIGS. 6a and 6b depict other package designs. As observed in FIG. 6a, an interposer 604 is placed upon the package substrate 603 and multiple semiconductor chips 605 are placed upon the interposer 604. The interposer 604 is a circuit board whose die side I/Os 607 are smaller than the package substrate’s die side I/Os 605. The interposer 604 contains wiring structures to map the package substrate’s die side I/Os 605 to the I/Os 606 of the semiconductor chips 605.

The interposer 604 can be used, e.g., in circumstances where the substrate’s manufacturing process does not support the manufacturing of I/Os that are small enough to mate with the I/Os of the semiconductor chips 605, or, as a substrate for the semiconductor chips 605 to, e.g., support their shipment and attachment as a unit/module. Although more than multiple semiconductor chip 605 are shown in FIG. 6a, an interposer 604 can be used in packages having only semiconductor chip.

FIG. 6b shows the package of FIG. 6a but with an embedded semiconductor chip (ESC) 608 within the interposer 604. Here, the semiconductor chips 607 are to send very high speed signals between each another through extremely small I/Os. Because a semiconductor chip can be manufactured to have finer wire structures and I/Os than printed circuit boards, the ESC 608 has I/Os that can connect to the extremely small I/Os of the semiconductor chips 607 and contains fine pitched wires to transport the high speed signals between the semiconductor chips 607.

Notably, the different dielectric material choices for different dielectric layers depending on the uses of their respective, neighboring metal layers, as described at length above, can be applied to any of a package substrate and an interposer.

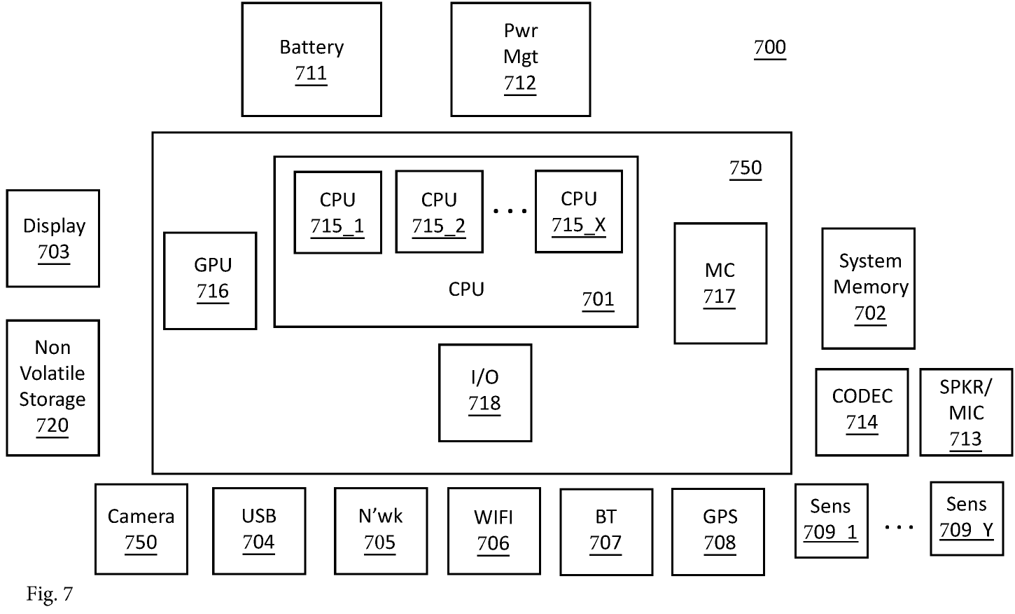

FIG. 7 provides an exemplary depiction of a computing system 700 (e.g., a smartphone, a tablet computer, a laptop computer, a desktop computer, a server computer, etc.). As observed in FIG. 7, the basic computing system 700 may include a central processing unit 701 (which may include, e.g., a plurality of general purpose processing cores 715_1 through 715_X) and a main memory controller 717 disposed on a multi-core processor or applications processor, system memory 702 (also referred to as main memory), a display 703 (e.g., touchscreen, flat-panel), a local wired point-to-point link (e.g., USB) interface 704, various network I/O functions 705 (such as an Ethernet interface and/or cellular modem subsystem), a wireless local area network (e.g., WiFi) interface 706, a wireless point-to-point link (e.g., Bluetooth) interface 707 and a Global Positioning System interface 708, various sensors 709_1 through 709_Y, one or more cameras 710, a battery 711, a power management control unit 712, a speaker and microphone 713 and an audio coder/decoder 714.

An applications processor or multi-core processor 750 may include one or more general purpose processing cores 715 within its CPU 701, one or more graphical processing units 716, a memory management function 717 (e.g., a memory controller) and an I/O control function 718 (e.g., l/O control hub or peripheral control hub (PCH)). The general purpose processing cores 715 typically execute the operating system and application software of the computing system. The graphics processing unit 716 typically executes graphics intensive functions to, e.g., generate graphics information that is presented on the display 703. The main memory controller 717 interfaces with the system memory 702 to write/read data to/from system memory 702.

The power management control unit 712 generally controls the power consumption of the system 700. Each of the touchscreen display 703, the communication interfaces 704-707, the GPS interface 708, the sensors 709, the camera(s) 710, and the speaker/microphone codec 713, 714 all can be viewed as various forms of l/O (input and/or output) relative to the overall computing system including, where appropriate, an integrated peripheral device as well (e.g., the one or more cameras 710). Depending on implementation, various ones of these I/O components may be integrated on the applications processor/multi-core processor 750 or may be located off the die or outside the package of the applications processor/multi-core processor 750. The computing system also includes non-volatile storage 720 which may be the mass storage component of the system (e.g., a hard disk drive, a solid state drive, etc.).

The computer system can include one or more packaged semiconductor chips whose chip package has a multi-layer substrate that surrounds layers of circuit structures with different dielectric materials as described at length above.

Embodiments of the invention may include various processes as set forth above. The processes may be embodied in machine-executable instructions. The instructions can be used to cause a general-purpose or special-purpose processor to perform certain processes. Alternatively, these processes may be performed by specific/custom hardware components that contain hardwired logic circuitry or programmable logic circuitry (e.g., field programmable gate array (FPGA), programmable logic device (PLD)) for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

1. An apparatus, comprising:
a semiconductor chip package substrate comprising alternating metal and dielectric layers, wherein, first and second ones of the dielectric layers that are directly above and directly below a first of the metal layers that is patterned to have supply and/or reference voltage structures have respectively higher dielectric constant (Dₖ) and higher dissipation factor (D_{f}) than third and fourth ones of the dielectric layers that are directly above and directly below a second of the metal layers that is patterned to have signal wires that are to transport signals having a pulse width of 1 ns or less.

2. The apparatus of claim 1 wherein the semiconductor chip package comprises a top stack of alternating metal and dielectric layers and a bottom stack of alternating metal and dielectric layers separated by one or more core dielectric layers.

3. The apparatus of claim 1 wherein the third and fourth ones of the dielectric layers have air pockets therein.

4. The apparatus of claim 1 wherein the air pockets are formed with hollow particles that are embedded in the dielectric material.

5. The apparatus of claim 1 wherein the third and fourth ones of the dielectric layers comprise non polar molecular structures.

6. The apparatus of claim 5 wherein the non polar molecular structures comprise non-polar cross-linkers.

7. The apparatus of claim 5 wherein the non polar molecular structures comprise non-polar polymer backbone material.

8. A computer comprising:
a solid state drive interface;
a networking interface;
a system memory; and,
a processor packaged in a semiconductor chip package substrate, the semiconductor chip package substrate comprising alternating metal and dielectric layers, wherein, first and second ones of the dielectric layers that are directly above and directly below a first of the metal layers that is patterned to have supply and/or reference voltage structures have respectively higher dielectric constant (Dₖ) and higher dissipation factor (D_{f}) than third and fourth ones of the dielectric layers that are directly above and directly below a second of the metal layers that is patterned to have signal wires that are to transport signals having a pulse width of 1 ns or less.

9. The apparatus of claim 1 wherein the semiconductor chip package comprises a top stack of alternating metal and dielectric layers and a bottom stack of alternating metal and dielectric layers separated by one or more core dielectric layers.

10. The apparatus of claim 1 wherein the third and fourth ones of the dielectric layers have air pockets therein.

11. The apparatus of claim 1 wherein the air pockets are formed with hollow particles that are embedded in the dielectric material.

12. The apparatus of claim 1 wherein the third and fourth ones of the dielectric layers comprise non polar molecular structures.

13. The apparatus of claim 5 wherein the non polar molecular structures comprise non-polar cross-linkers.

14. The apparatus of claim 5 wherein the non polar molecular structures comprise non-polar polymer backbone material.

15. A method, comprising:
depositing a first metal layer on a first dielectric layer having a first dielectric constant and a first dissipation factor constant;
patterning the first metal layer to form wires that are to transport signals having a pulse width of 1 ns or less;
deposing a second dielectric layer on the first metal layer having the first dielectric constant and the first dissipation factor constant;
depositing a second metal layer on a third dielectric layer having a second dielectric constant that is higher than the first dielectric constant and a second dissipation factor constant that is higher than the first dissipation factor constant;
patterning the second metal layer to form voltage supply and/or reference circuit structures; and,
deposing a fourth dielectric layer on the second metal layer having the second dielectric constant and the second dissipation factor constant.

16. The method of claim 15 wherein the first and second dielectric layers have air pockets therein.

17. The method of claim 16 wherein the air pockets are formed with hollow particles that are embedded in the dielectric material.

18. The apparatus of claim 15 wherein the first and second dielectric layers comprise non polar molecular structures.

19. The method of claim 18 wherein the non polar molecular structures comprise non-polar cross-linkers.

20. The method of claim 18 wherein the non polar molecular structures comprise non-polar polymer backbone material.
